(19) United States
(12) Patent Application Publication
(10) Pub. No.: US 2022/0239250 A1
(43) Pub. Date: Jul. 28, 2022

(54) SEALING ASSEMBLY AND ARRAY OF PHOTOVOLTAIC PANELS INCORPORATING SEALING ASSEMBLY

(71) Applicant: R&MS SOLUTIONPARTNER VERWALTUNGS GmbH, Strassen (LU)

(72) Inventors: Reiner MACK, Waigandshain (DE); Bernd GIESSLER, Waigandshain (DE)

(21) Appl. No.: 17/721,968

(22) Filed: Apr. 15, 2022

Related U.S. Application Data
(63) Continuation of application No. PCT/EP2020/078879, filed on Oct. 14, 2020.

(30) Foreign Application Priority Data
Oct. 15, 2019 (EP) 19203436.1

(51) Int. Cl. H02S 30/10; H02S 20/23

(52) U.S. Cl. CPC H02S 30/10; H02S 20/23

(57) ABSTRACT

A seal assembly for arrangement between a first and a second photovoltaic panel is disclosed. The first and the second photovoltaic panel each includes an upper layer and a lower layer, wherein the upper layer is offset with respect to the lower layer at first and second side edges, such that the upper layer of the first photovoltaic panel at its second side edge partially overlaps the lower layer of the second photovoltaic panel at its first side edge. The seal assembly include an upper abutment part, a lower abutment part, and an intermediate part connecting the upper abutment part with the lower abutment part and configured for being arranged between the upper layer of the first photovoltaic panel and the lower layer of the second photovoltaic panel. Also, arrays of solar panels and roof structures including such seal assemblies are disclosed.

### CROSS-REFERENCE TO RELATED APPLICATIONS

The present application relates to and claims the benefit and priority to International Application No. PCT/EP2020/078879 filed Oct. 14, 2020, which claims the benefit and priority to European Patent Application No. 19203436.1 filed on Oct. 15, 2019.

### FIELD

The present disclosure relates to a sealing assembly. More particularly, the present disclosure relates to a sealing assembly arranged between two photovoltaic panels. The present disclosure furthermore relates to an array of photovoltaic panels incorporating such a sealing assembly and to a roof structure comprising such an array.

### BACKGROUND

An ever-growing energy demand has made it necessary to consider solutions coming from renewable energy sources for the production of energy. Energy from water and air flows, biomass and sun are some of the most promising of such sources.

Photovoltaic (PV) cells are electrical devices that convert the energy of light directly into electricity by the photovoltaic effect. PV cells are typically arranged in modules that comprise a plurality of photovoltaic cells. Such modules are called solar panels. Arrays of panels are typically used to generate enough electricity that would be meaningful to store in batteries or to directly power electricity consuming devices. However, such arrays may use a lot of space, which cannot otherwise be used. For example, it is known to place large arrays of photovoltaic panels in fields or to place a single panel or a smaller array of panels on top of buildings.

Roofs of houses and buildings are attractive places for positioning PV panels or modules, because they receive a lot of sun light. It is known to use PV or “solar” roof tiles to cover part of a roof of a building. Such solar roof tiles perform the function of a traditional roof tile, but at the same time can produce electricity through energy conversion of solar rays. Just as traditional roof tiles, the solar roof tiles are to be connected to a framework of a roof, and they protect the underlying structure from weather influences, and particularly they keep rain out.

The existing solar roof tiles suffer from various drawbacks. Existing solar roof tiles may be complicated to install. The process of placing the solar roof tiles can therefore be cumbersome and require a long time. Also, since solar roof tiles are made from more fragile materials, it frequently happens that the solar roof tiles are damaged during installation. This can affect the functioning of the photovoltaic cells, it may lead to leaks, and it can be aesthetically unpleasing. Furthermore, it needs to be ensured that even in strong winds or storms, the roof tiles stay in place. This represents another important requirement for roof tiles, which has not always been met by existing solar roof tiles.

U.S. Publication No. 2018/0166600 describes a photovoltaic module employing an array of photovoltaic cells disposed between two optically transparent substrates such as to a defined closed-loop peripheral area of the module that does not contain a photovoltaic cell. The module is sealed with a peripheral seal along the perimeter. The two substrates may be laterally offset with respect to each other.

Further improvements in PV roof tiles are still desired.

### SUMMARY

In a first aspect, the present disclosure provides a seal assembly for arrangement between a first and a second photovoltaic panel. The first and the second photovoltaic panel have a first side edge, and a second side edge opposite to the first side edge, and comprise an upper layer and a lower layer, wherein the upper layer is offset with respect to the lower layer at the first and second side edges, such that the upper layer of the first photovoltaic panel at its second side edge partially overlaps the lower layer of the second photovoltaic panel at its first side edge. The seal assembly comprises an upper abutment part for abutting the upper layers of the first and second photovoltaic panels, a lower abutment part for abutting the lower layers of the first and second photovoltaic panel, and an intermediate part connecting the upper abutment part with the lower abutment part and configured for being arranged between the upper layer of the first photovoltaic panel and the lower layer of the second photovoltaic panel.

In accordance with this aspect, a seal assembly is provided which enables easier installation of photovoltaic panels. The photovoltaic panels have offset layers, and the seal assembly is adapted to these offset layers, such that a photovoltaic panel can be laid, a seal can be laid against the panel and partly on top of it, and the subsequent panel can be laid. The process can be faster than in prior art solutions because there is no separate process for sealing after laying. The risk of damaging the photovoltaic panels is reduced because the sealing assembly can avoid the more fragile parts of the panels touching each other.

In some examples, a top edge of the upper abutment part of the sealing assembly may be substantially level with a top surface of the first photovoltaic panel and a top surface of the second photovoltaic panel. If the top surfaces of the photovoltaic panels are level or “flush” with the sealing, no dirt, dust, and moist can accumulate against the sides of the sealing or between the photovoltaic panels. Not only can aesthetics be improved in this way, but also the functioning of the panels, and maintenance needs may be reduced.

In some examples, a lower edge of the intermediate part may comprise a plurality of protrusions to form a labyrinth seal. Leaks of water may be avoided or reduced in this manner.

In another aspect, an array of photovoltaic panels comprising a first photovoltaic panel and a second photovoltaic panel is provided. The photovoltaic panels have a first side edge, and a second side edge opposite to the first side edge, and an upper layer and a lower layer, wherein the upper layer is offset with respect to the lower layer at the first and second side edges, such that the upper layer of the first photovoltaic panel partially overlaps the lower layer of the second photovoltaic panel. The array further comprises the seal assembly according to any of the examples herein disclosed, arranged between the first and second photovoltaic panels.

In yet a further aspect, a roof structure for a building comprising a supporting framework, and the array of photovoltaic panels according to any of the herein disclosed examples is provided.

### BRIEF DESCRIPTION OF THE DRAWINGS

Particular implementations will be described in the following by way of non-limiting examples, with reference to the appended drawings, in which:

FIGS. 1A and 1B illustrate an exploded view of an example of a roof structure according to the present disclosure;

FIGS. 2A and 2B illustrate cross-sectional views of an array of photovoltaic panels and a sealing assembly according to an example of the present disclosure; and

FIGS. 3A and 3B schematically illustrate an example of a build-up of a roof structure.

### DETAILED DESCRIPTION

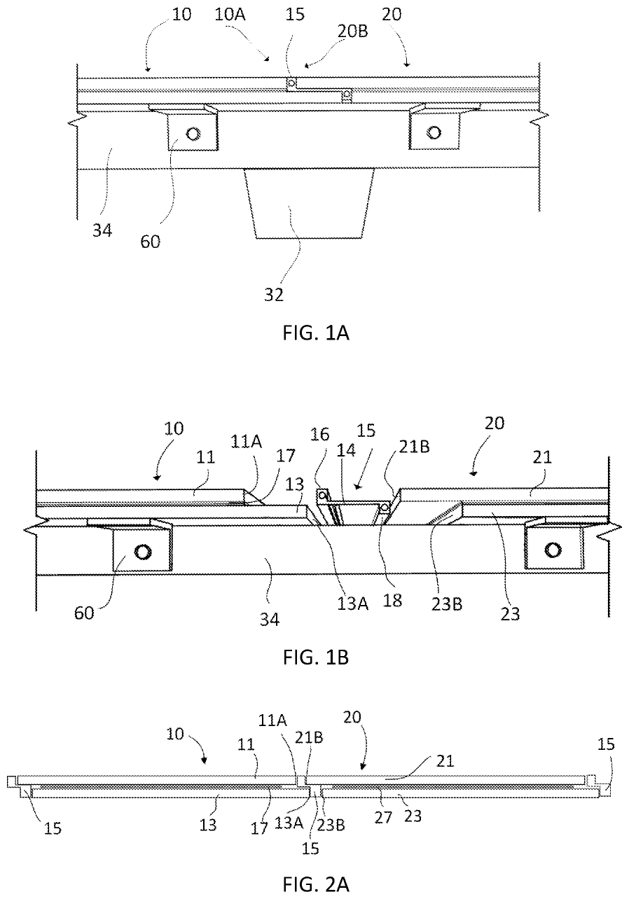

FIGS. 1A and 1B illustrate an example of part of a roof structure. FIG. 1A shows a side view of an assembly whereas FIG. 1B shows an exploded view of the various components of the assembly.

The roof structure according to this example includes a framework supporting photovoltaic panels. The photovoltaic panels of this example function as solar roof tiles. The photovoltaic panels 10, 20 comprise photovoltaic cells. These cells can be irradiated by the sun during the day and the cells are configured to convert solar energy into electricity. Electrical power generated by the photovoltaic panels may be used for electrical consumption in a household living under the roof structure. Additionally, or alternatively, the electrical power may be directed towards an energy storage such as a battery for later consumption. Additionally, or alternatively, the electrical power may be provided to the electrical grid.

At the same, the photovoltaic panels may function as roof tiles, i.e. they protect the inside of a building under the roof structure from the weather, particularly rain. Appropriate sealing between the photovoltaic panels is therefore important.

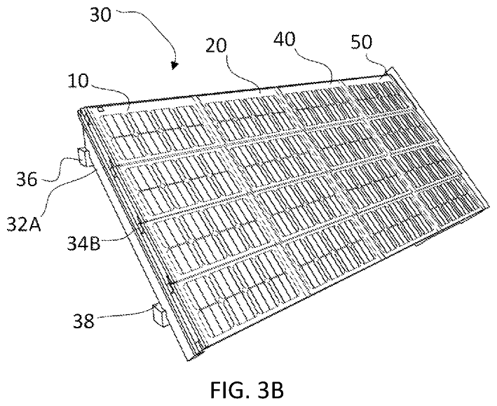

In the example of FIGS. 1A and 1B, a supportive framework is provided. The supportive framework may include a plurality of horizontal beams 34 and vertical beams 32. The horizontal beams 34 are supported by a plurality of vertical beams 32, which extend between a base and a top. In this particular example, the beams may be wooden beams. Horizontal beams extend substantially horizontally, whereas vertical beams may have a slope of e.g. 10-45° with respect to a horizontal place. This may be seen e.g. in FIG. 3A. Even though the beams are herein referred to as vertical beams, they clearly are not to be understood as arranged entirely vertically in use.

A first photovoltaic panel 10 is shown to be arranged next to a second photovoltaic panel 20. The photovoltaic panels 10, 20 may be attached to the horizontal beams 34 using a mounting bracket, or ankle plate 60. The mounting bracket may be bolted to beams 34 and attached to a photovoltaic panel using e.g. an adhesive. In other examples, different attachment systems may be used involving e.g. clamps for clamping the photovoltaic panels.

Each of the photovoltaic panels 10, 20 comprises an upper layer 11, and a lower layer 13. In between the upper layer 11 and lower layer 13, one or more PV cells 17 may be arranged. Each panel may comprise a plurality of interconnected PV cells.

It may be seen that the upper layers of the PV panels are offset with respect to the lower layers. The upper layer 11, 21 is offset with respect to the lower layer 13, 23 at the first and second side edges, such that the upper layer 21 of the second photovoltaic panel 20 at its first side edge partially overlaps the lower layer 13 of the first photovoltaic panel 10 at its second side edge.

This will be illustrated in more detail in subsequent figures. The offset between the upper layers and lower layers means that at a first edge 20B of the photovoltaic panel 20, the upper layer of photovoltaic panel 20 overlaps the lower layer of adjacent photovoltaic panel 10. At the opposite edge (not shown) of photovoltaic panel 20, its bottom layer may be arranged underneath an upper layer of a further adjacent photovoltaic panel.

In FIGS. 1A and 1B, a sealing assembly 15 may be seen to be arranged between photovoltaic panel 10 and photovoltaic panel 20. It may be seen that the seal assembly 15 comprises an upper abutment part 16 for abutting the upper layers 11, 21 of the first 20 and second photovoltaic panels 10, and a lower abutment part 18 for abutting the lower layers 13, 23 of the first 20 and second photovoltaic panel 10. The seal assembly further comprises an intermediate part 14 connecting the upper abutment part 16 with the lower abutment part 18 and configured for being arranged between the upper layer 21 of the first photovoltaic panel 20 and the lower layer 13 of the second photovoltaic panel 10.

More particularly, in this example, the upper abutment part 16 is arranged between first side edge 21B of upper layer 21 of panel 20, and second side edge 11A of the upper layer 11 of solar panel 10. And lower abutment part 18 is arranged between second side edge 13A of lower layer 13 of solar panel 10 and first side edge 23B of lower layer 23 of solar panel 20.

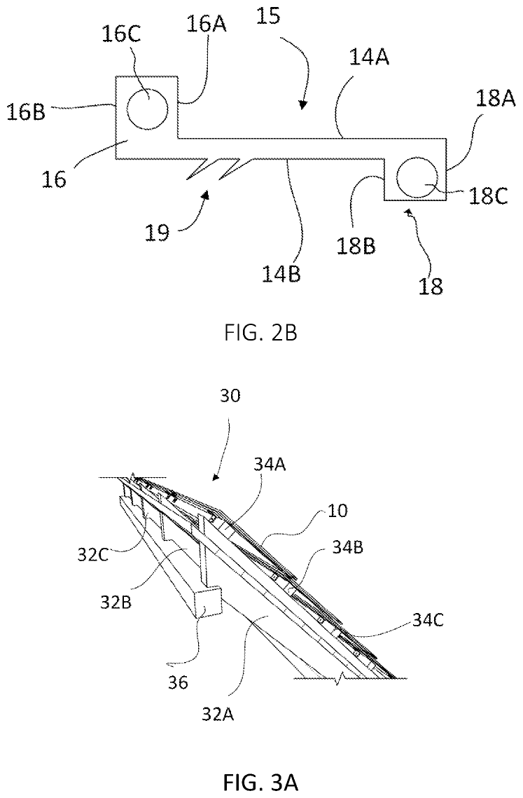

More details will be illustrated with reference to FIGS. 2A and 2B.

FIGS. 2A and 2B illustrate cross-sectional views of an array of photovoltaic panels and sealing assemblies according to an example of the present disclosure arranged between neighboring photovoltaic panels. FIGS. 2A and 2B illustrate a seal assembly 15 for arrangement between a first 20 and a second photovoltaic panel 10, the first 20 and the second photovoltaic panel 10 having a first side edge, and a second side edge opposite to the first side edge, and comprising an upper layer 11, 21 and a lower layer 13, 23. It may be seen that the same seal assembly may be arranged at opposite ends of the shown photovoltaic panels.

FIG. 2B shows how in this example the upper abutment part 16 comprises a first side surface 16A for contacting a first side edge 21B of the upper layer 21 of photovoltaic panel 20. The upper abutment part in this example further comprises a second side surface 16B for contacting a second side edge 11A of the upper layer 11 of photovoltaic panel 10.

Similarly, the lower abutment part may comprise a first surface 18A for contacting a first side edge 23B of the lower layer 23 of photovoltaic panel 20, and a second side surface 18B for contacting a second side edge 13A of the lower layer 13 of photovoltaic panel 10.

Intermediate part 14 connects the abutment portion 16 with abutment portion 18. The intermediate part may have a top surface 14A arranged to enter into contact with upper layer 21 of photovoltaic panel 20 and a bottom surface 14B configured to enter into contact with lower layer 13 of photovoltaic panel 10.

Even though these explanations are only given for one side edge, where upper layer 23 of photovoltaic panel 20 overlaps with lower layer 11 of photovoltaic panel 10, it should be clear that a similar seal assembly 15 may be arranged at the opposite edge of photovoltaic panel 20, and also at the opposite side edge of photovoltaic panel 10, and at side edges of subsequent photovoltaic panels in a row.

As shown, a top edge 16D of the upper abutment part is substantially level with a top surface of the first photovoltaic panel 10 and a top surface of the second photovoltaic panel 20. By arranging the upper abutment part 16 flush with the photovoltaic panels, accumulation of dirt, moist, dust, leaves and other against the sealing assembly 15 or in between panels 10, 20 may be avoided. Growth of moss can be avoided in this manner. This can reduce the need for cleaning and maintenance and can even lead to an increase in electrical power generation and/or an increase in the life expectancy of the photovoltaic panels.

The height of the upper abutment part may substantially correspond to the thickness of the upper layer 11, 21 of the photovoltaic panels. A thickness of the intermediate part 14 may generally correspond to the thickness or gap between the upper and lower layers of the solar panels. A height of the lower abutment part 18 may be shorter than the thickness of the lower layers 13, 23 of the photovoltaic panels. The material usage may be reduced by making these lower abutment parts slightly shorter, and to perform their function and avoid damage between panels it is not necessary to extend to the lower edge of the panels.

As may be seen in FIG. 2B, a bottom surface 14B of the intermediate part 14 may comprise a plurality of protrusions to form a labyrinth seal 19. A labyrinth seal is a seal that provides a tortuous path to prevent leakage, and in this particular example, the seal is arranged to prevent rainwater from dripping to underneath the roof structure. It should be clear that the number of protrusions of a labyrinth seal may be varied.

It may also be seen that the upper abutment part 16 and/or the lower abutment part 18 may comprise a structural member 16C, 18C. The main body of the sealing assembly 15 including upper abutment part, intermediate part and lower abutment part may be made e.g. from an elastomer, rubber or silicone material. Such materials may also include elements to increase strength and/or stiffness like glass fibers or carbon fibers. In an example, to increase strength and stiffness, the structural members 16C and 18C of the respective upper abutment part and lower abutment part may comprise e.g. a rod or bar of a stiff polymer or metal. Providing relatively stiff upper and lower abutment parts may increase ease of handle for operators that have to lay the seal.

In some examples, the sealing assembly may be provided on a roll and suitable lengths may be cut off as needed for a specific array of panels. In other examples, the sealing assembly is provided and delivered of a specific length corresponding to the width of the panels for which it is to be used.

In some examples, the upper layer 11, 21 of the first and second photovoltaic panels 10, 20 may comprise a glass plate. Such a glass plate serves to provide structural strength and rigidity to the panels. The glass plate further protects the PV cells from hail or impact of objects. In some non-illustrated examples, the photovoltaic panels may comprise a frame, such as an aluminum frame.

In some examples, the lower layer 13, 23 of the first and second photovoltaic panels may comprise a solar back sheet.

In some examples, the first and the second photovoltaic panels may comprise a plurality of photovoltaic cells 17, 27 encapsulated in a polymer matrix. The photovoltaic cells may be crystalline cells, but other types of cells could be used. The polymer matrix may be formed by or may comprise Ethylene-vinyl acetate (EVA).

In some examples, the active layer (i.e. in this example the encapsulated photovoltaic cells) may be arranged between the upper and the lower layer. The separation of layers as illustrated herein may facilitate manufacture of the panels.

In some examples, a length of the seal assembly may be larger than a length of the first side edge of the first and second photovoltaic panels. Depending on the structure, a plurality of panels may be laid side by side, then a sealing assembly may be placed extending along the first side edge of the plurality of panels. Then subsequent panels may be placed against the sealing assembly.

In some examples, the first and second photovoltaic panels may further comprise a third side edge and a fourth side edge opposite to the third side edge, wherein the upper layer and the lower layer of the first photovoltaic panel and second photovoltaic panel at the third and fourth side edges are not offset. In roof structures, a lower edge (e.g. third edge) of photovoltaic panels of a higher row may overlap an upper portion (at the fourth edge) of the lower row of panels. This may be seen e.g. in FIGS. 3A and 3B.

In other examples, the photovoltaic panels may also have an offset at the third and fourth side edges. In such cases, similar seal assemblies may be arranged between photovoltaic panels at the third and fourth side edges.

FIGS. 3A and 3B schematically illustrate an example of a build-up of a roof structure. The roof structure of this example comprises a supporting framework, and an array of photovoltaic panels. The photovoltaic panels or photovoltaic roof tiles may include a plurality of rows. In a top row, photovoltaic panels 10, 20, 40 and 50 are shown.

The supporting framework in this example comprises a top beam 36, a bottom beam 38, a plurality of vertical beams 32A, 32B, etc. extending between the top beam 36 and the bottom beam 38, and a plurality of horizontal beams 34A, 34B, 34C etc. which are arranged substantially in parallel with the top beam and the bottom beam.

The first and second photovoltaic panels 10, 20 may be attached to one or more of the beams of the supporting framework, specifically the first and second photovoltaic panels 10, 20 may be attached to one of the horizontal beams 34A, 34B etc. More specifically, the photovoltaic panels may substantially span the distance between neighboring horizontal beams 34. In some examples, the photovoltaic panels may be secured to two horizontal beams.

One method of securing the photovoltaic panels to the beams was illustrated in FIGS. 1A and 1B. The first and second photovoltaic panels may be attached to one of the beams of the supporting framework with one or more metal brackets. Attachment of the panels may include clamps, adhesives, screws, or combinations hereof. Because of the partial overlapping of neighboring panels in a row, they also provide support to each other.

It may be seen in FIGS. 3A and 3B, that a bottom edge of a higher row of panels (e.g. the top row comprising panels, 10, 20, 40, 50) overlaps an upper edge of a lower row of panels. It may be seen however that the active material i.e. the photovoltaic cells are not covered by neighboring panels.

With the techniques and arrangements disclosed herein, entire roofs or parts of roofs may be covered with solar roof tiles in an efficient, aesthetically pleasing and cost-effective manner.

Although only a number of particular embodiments and examples of the invention have been disclosed herein, it will be understood by those skilled in the art that other alternative embodiments and/or uses of the invention and obvious modifications and equivalents thereof are possible. Furthermore, the present invention covers all possible combinations of the particular embodiments described. Thus, the scope of the present invention should not be limited by particular embodiments, but should be determined only by a fair reading of the claims that follow.

What is claimed is:

1. A seal assembly for arrangement between a first photovoltaic panel and a second photovoltaic panel, each of the first and second photovoltaic panels including an upper layer and a lower layer with each of the upper and lower layers having a first side edge and a second side edge opposite the first side edge, the seal assembly comprising:
an upper abutment part having a first side for abutting the second side edge of the upper layer of the first photovoltaic panel and a second side for abutting the first side edge of the upper layer of the second photovoltaic panel;
a lower abutment part spaced apart from the upper abutment part, the lower abutment part having a first side for abutting the second side edge of the lower layer of the first photovoltaic panel and a second side for abutting the first side edge of the lower layer of the second photovoltaic panel; and
an intermediate part connecting the upper abutment part with the lower abutment part and configured for being arranged between the upper layer of the second photovoltaic panel and the lower layer of the first photovoltaic panel.

2. The seal assembly according to claim 1, wherein a top edge of the upper abutment part is configured to be level with a top surface of the first photovoltaic panel and a top surface of the second photovoltaic panel.

3. The seal assembly according to claim 1, wherein the upper abutment part has a first thickness and the lower abutment part has a second thickness less than the first thickness.

4. The seal assembly according to claim 1, wherein a bottom surface of the intermediate part comprises a plurality of protrusions configured to form a labyrinth seal.

5. The seal assembly according to claim 1, wherein one or both of the upper and lower abutment parts includes a stiffening element encapsulated therein.

6. The seal assembly according to claim 1, wherein the upper abutment part, the lower abutment part and the intermediate part comprise a monolithic structure made of an elastomer.

7. An arrangement of photovoltaic panels comprising:
a first photovoltaic panel having an upper layer and a lower layer, each of the upper and lower layers of the first photovoltaic panel having a first side edge and a second side edge opposite to the first side edge:
a second photovoltaic panel having an upper layer and a lower layer, each of the upper and lower layers of the second photovoltaic panel having a first side edge and a second side edge opposite to the first side edge;
the first side edge of the upper layer of the second photovoltaic panel is offset with respect to the second side edge of the lower layer of the first photovoltaic panel such that the upper layer of the second photovoltaic panel partially overlaps the lower layer of the first photovoltaic panel; and
a seal assembly arranged between the first and second photovoltaic panels, the seal assembly comprising:
an upper abutment part having a first side for abutting the second side edge of the upper layer of the first photovoltaic panel and a second side for abutting the first side edge of the upper layer of the second photovoltaic panel;
a lower abutment part spaced apart from the upper abutment part, the lower abutment part having a first side for abutting the second side edge of the lower layer of the first photovoltaic panel and a second side for abutting the first side edge of the lower layer of the second photovoltaic panel; and
an intermediate part connecting the upper abutment part with the lower abutment part and configured for being arranged between the upper layer of the second photovoltaic panel and the lower layer of the first photovoltaic panel.

8. The arrangement of photovoltaic panels according to claim 7, wherein the upper abutment part has a top edge that is level with a top surface of each of the first and second photovoltaic panels.

9. The arrangement of photovoltaic panels according to claim 7, wherein a length of the seal assembly is larger than a length of the first side edge of the first and second photovoltaic panels.

10. The arrangement of photovoltaic panels according to claim 7, wherein each of the first and second photovoltaic panels further comprises a third side edge and a fourth side edge opposite to the third side edge, wherein
the upper layer and the lower layer of the first photovoltaic panel at the third and fourth side edges are not offset, and wherein
the upper layer and the lower layer of the second photovoltaic panel at the third and fourth side edges are not offset.

11. The arrangement of photovoltaic panels according to claim 7, wherein the upper layer of each of the first and second photovoltaic panels comprises a glass plate.

12. The arrangement of photovoltaic panels according to claim 7, wherein the lower layer of each of the first and second photovoltaic panels comprises a solar back sheet.

13. The arrangement of photovoltaic panels according to claim 7, wherein each of the first and the second photovoltaic panels comprises a plurality of photovoltaic cells encapsulated in a polymer matrix.

14. The arrangement of photovoltaic panels according to claim 13, wherein the photovoltaic cells are crystalline cells.

15. The arrangement of photovoltaic panels according to claim 13, wherein the polymer matrix comprises Ethylene-vinyl acetate (EVA).

16. The arrangement of photovoltaic panels according to claim 13, wherein the encapsulated photovoltaic cells are arranged between the upper and the lower layers of the respective first and second photovoltaic panels.

17. The arrangement of photovoltaic cells according to claim 7, wherein the assembled first photovoltaic panel, second photovoltaic panel and seal assembly comprise a roof structure for a building.

18. The arrangement of photovoltaic panels according to claim 17, further comprising a supporting framework that includes a top beam, a bottom beam, a plurality of vertical beams extending between the top beam and the bottom beam, and a plurality of lateral beams which are arranged in parallel with the top beam and the bottom beam, the first and second photovoltaic panels being attached to one or more of the top beam, lower beam, plurality of vertical beams and plurality of lateral beams.

19. The arrangement of photovoltaic panels according to claim 18, wherein each of the first and second photovoltaic panels is attached to at least one of the plurality of lateral beams.

20. The arrangement of photovoltaic panels according to claim 18, wherein the first and second photovoltaic panels are attached to the supporting framework with one or more metal brackets.
